(19) United States
(12) Patent Application Publication
(10) Pub. No.: US 2006/0113544 A1
(43) Pub. Date: Jun. 1, 2006

(54) Semiconductor light-emitting device, method for manufacturing same, and linear light source

(76) Inventors: Koji Otsuka, Saitama (JP); Hitoshi Murofushi, Saitama (JP); Shiro Takeda, Saitama (JP)

Correspondence Address: BACHMAN & LAPOINTE, P.C., 900 CHAPEL STREET, SUITE 1201, NEW HAVEN, CT, 06510, US

(21) Appl. No.: 10/538,387

(22) PCT Filed: Nov. 28, 2003
(86) PCT No.: PCT/JP03/15242

§ 371 Date: Jun. 13, 2005

(30) Foreign Application Priority Data
Dec. 13, 2002 (JP) 2002-362663
Jan. 17, 2003 (JP) 2003-9710

(51) Int. Cl. H01S 5/00; H01L 29/15

(52) U.S. Cl. 257/76; 372/43.01

(57) ABSTRACT

A semiconductor light-emitting device comprises an elongated light transmitter 2; a pair of metallic heat sinks 4 disposed at both ends 2a of light transmitter 2 in a perpendicular relation to light transmitter 2. A linear light source comprises an elongated light transmitter 2 having an irradiation surface 2e; semiconductor light-emitting elements 3 for respectively emitting light into light transmitter 2 from both ends 2a thereof; and half-mirrors 20 mounted in light transmitter 2 for reflecting light emitted from light-emitting elements 3 toward the outside of light transmitter 2 through irradiation surface 2e. With these semiconductor light-emitting device and linear light source, light from the semiconductor light-emitting element as a point light source can be transformed into a linear light with the generally uniform luminance.

### TECHNICAL FIELD

This invention relates to a semiconductor light-emitting device, in particular of the type converting a point light source from a semiconductor light-emitting element into a linear light irradiation.

### BACKGROUND OF THE INVENTION

A known typical liquid crystal display (LCD) of transmission type has a cold cathode fluorescent lighting tube (CCFL tube) available as a backlight source. Such LCDs have widely been applied to those or the like for television monitors, mobile personal computers and cellular phones. A CCFL tube comprises a glass tube for sealing mercury vapor therein, a pair of electrodes provided at both ends of glass tube, and a fluorescent layer coated on an inner surface of the glass tube wherein electric voltage is applied across electrodes to produce electric discharge between electrodes for mercury vapor excitation by electric energy; thereby mercury vapor generates ultra-violet light to generate a visible light of wavelength determined by the fluorescent material and irradiated out of the glass tube. When fluorescent layer contains three kinds of fluorescent material at the suitable mixture ratio which may generate three primary color lights, the tube can produce a white light consisting of mixed three primary color lights through three kinds of fluorescent material.

A typical CCFL tube used as a backlight source for LCD generates light of emission spectrums which have three sharp peaks in blue, green and red color wavelength areas, and color filters in LCD for forming three primary color pixels have transmission spectrums in wide ranges. Transmission spectrums for three primary color pixels in LCD are actually decided by light emission spectrums through CCFL tube, and it is very difficult to generate light colors of high purity only by transmission property through color filters which only function to filtrate lights in generous ranges without specifying boundaries of wavelength areas and to prevent mixture of transmission spectrum for two primary color components (for example, green and blue) into the remaining one pixel (for example, red pixel).

To determine an index of picture quality level for a display, usually a display is compared to the chromaticity reproduction area or gamut according to the broadcasting format for color television regulated by National Television System Committee (NTSC), however, white color light produced from CCFL tube contains each insufficient amount of red and green color components, in particular is inferior to red color rendering so that LCD cannot produce a bright red color light conformable to the regulations by NTSC when it utilizes CCFL tube as a white backlight source.

On the other hand, attempts have been made to develop technologies for utilizing semiconductor light-emitting elements such as light-emitting diodes (LEDs) as substitutes for CCFL tubes. Compared to white light source of bulb type such as an incandescent lamp or a hot or cold cathode fluorescent lighting tube, a semiconductor light-emitting element has the superior properties in that the latter has the higher mechanical impact strength, less amount of heat generated during operation, does not need application of high voltage thereto, does not bring about high frequency noise, and is ecological due to mercury-free light source. In an example of a semiconductor light-emitting element applied to a well-known backlight source of side-edge type wherein a light-emitting device is disposed along a side-edge of LCD, a plurality of semiconductor light-emitting elements are located toward side end surfaces of a transparent light guide plate formed of a light permeable resin such as acrylic resin. Light from semiconductor light-emitting elements is introduced into light guide plate from the side end surfaces, reflected in and out of the light guide plate from one surface thereof to irradiate the light on to liquid crystal panel from the back (for example, refer to Japanese Patent Disclosure No. 2002-43630, bridging pages 3 to 4, FIGS. 1 and 3).

Such a prior art arrangement of plural semiconductor light-emitting elements toward side end surfaces of light guide plate, however, is defective in that it is difficult to irradiate light from point light sources of plural semiconductor light-emitting elements onto a whole surface of guide plate with the uniform brightness, thus giving rise to imbalance in colorific tone.

Therefore, an object of the present invention is to provide a semiconductor light-emitting device for converting a point light source by a semiconductor light-emitting element into a linear light irradiation with the substantially uniform brightness, method for manufacturing same and linear light source.

### SUMMARY OF THE INVENTION

The semiconductor light-emitting device according to the present invention comprises an elongated light transmitter (2); a pair of metallic heat sinks (4) disposed on opposite ends (2a) of the transmitter (2); and a semiconductor light-emitting element (3) mounted each of the heat sinks (4) toward the transmitter (2). When the semiconductor light-emitting element (3) produces light of high brightness by passing heavy current through the semiconductor light-emitting element (3), heat generated during the lighting operation of the semiconductor light-emitting element (3) can be exhausted outside, thereby enabling the semiconductor light-emitting element (3) to continue the lighting for a long period of time with the high brightness. Also, light irradiated from the light-emitting element (3) is directly introduced into the transmitter (2) from the both ends thereof with the minimum amount of light leakage for high light transfer efficiency, and the transmitter (2) can convert the light into a linear light radiated outside from an outer peripheral surface (2b) of the transmitter (2) with the substantially uniform brightness throughout the whole longitudinal surface (2b). Whereas prior art CCFL tube emits light with the insufficient amount of red and green color components, light emission from the light-emitting element (3) contains full amount of red and green color components for light irradiation with the good colorific tone balance.

### BRIEF DESCRIPTION OF THE DRAWINGS

FIG. 1 is a sectional view of an embodiment of the semiconductor light-emitting device according to the present invention;

FIG. 2 is a sectional view of another embodiment of the semiconductor light-emitting device according to the present invention;

FIG. 3 is a perspective view showing a part of a light-emitting diode;

FIG. 4 is a plan view showing a part of a leadframe assembly;

FIG. 5 is a sectional view of a semiconductor light-emitting device with a reflector formed with a step;

FIG. 6 is a sectional view of a semiconductor light-emitting device which has a light transmitter formed into a bent shape;

FIG. 7 is a perspective view of a transmitter a portion of which being coated with a light reflective film;

FIG. 8 is a perspective view of a transmitter and a reflector separated from the transmitter for enveloping a half of the transmitter;

FIG. 9 is a gamut map showing a chromaticity reproductibility according to the CIE (Commission Internationale de I'Ecairage) Standard Colorimetric System;

FIG. 10 is a sectional view showing an embodiment of a linear light source according to the present invention;

FIG. 11 is a sectional view showing another embodiment of a linear light source according to the present invention;

FIG. 12 is a perspective view showing a method for providing a half-mirror in a light transmitter by sandwiching the half-mirror between cut segments of the light transmitter;

FIG. 13 is a perspective view showing a method for providing a half-mirror in a light transmitter by vapor deposition of a thin film layer on surfaces of cut segments of the light transmitter;

FIG. 14 is a sectional view of a linear light source provided with a pair of total reflection mirrors and two pairs of half-mirrors;

FIG. 15 is a sectional view of a linear light source which has a light transmitter formed into a bent shape;

FIG. 16 is a perspective view of a light transmitter a portion of which being formed with a light reflective film;

FIG. 17 is a perspective view of a transmitter and a reflector separated from the transmitter for enveloping the transmitter; and

FIG. 18 is a sectional view of a linear light source with a reflector formed with a step.

### BEST MODE FOR CARRYING OUT THE INVENTION

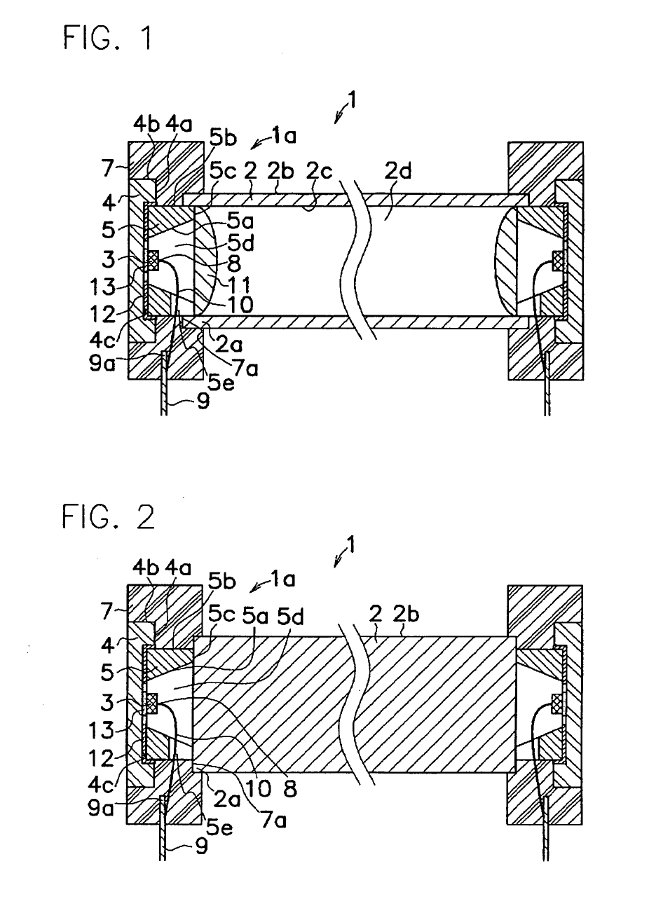

Embodiments of the semiconductor light-emitting device and manufacture thereof are described hereinafter with reference to FIGS. 1 to 18.

As shown in FIGS. 1 and 2, the semiconductor light-emitting device of an embodiment according to the present invention, comprises an elongated baculiform light transmitter 2; a pair of metallic heat sinks 4 disposed at opposite ends 2a of and perpendicular to transmitter 2; and a light-emitting diode chip 3 as a semiconductor light-emitting element mounted each of heat sinks 4 toward transmitter 2. Transmitter 2 is formed of light-transmissible material such as transparent or translucent glass or resin such as for example epoxy, acrylic, polyimide or polycarbonate resin. FIG. 1 illustrates a semiconductor light-emitting device 1 which comprises hollow cylindrical light transmitter 2 formed with a cavity 2d, and FIG. 2 represents a semiconductor light-emitting device 1 which comprises solid cylindrical light transmitter 2 without cavity. Cylindrical cavity 2d is filled with gas such as air or nitrogen gas, but transparent or translucent gel or solid resin may be charged or filled in cavity 2d.

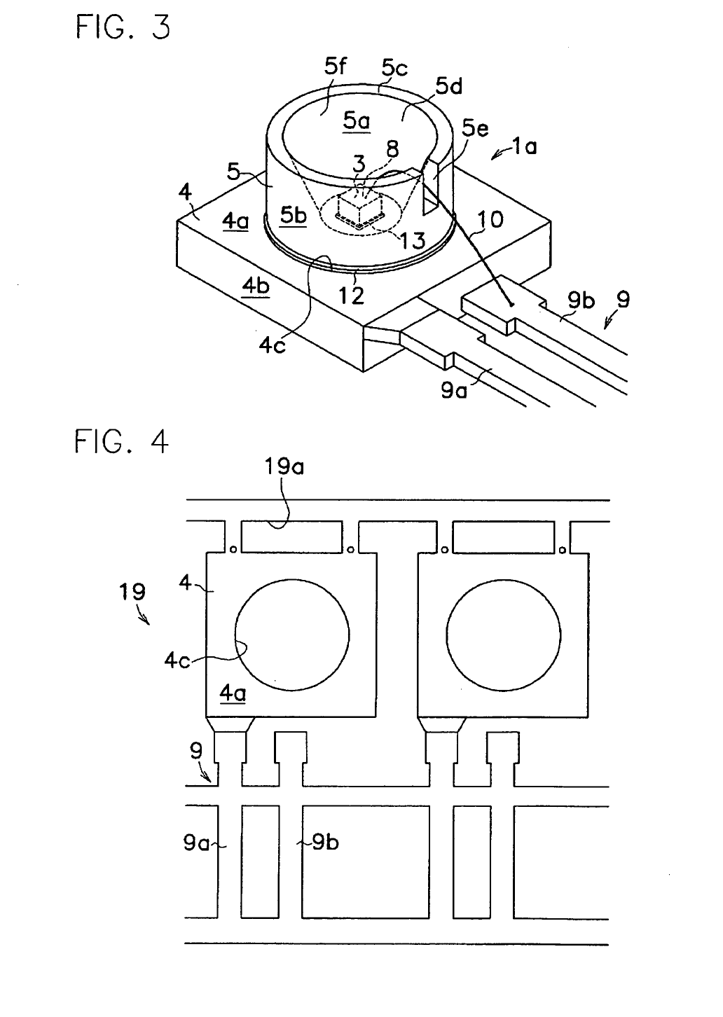

Provided at both ends 2a of light transmitter 2, are light-emitting diode device 1a each which comprises a metallic heat sink or cooling plate 4, and a light-emitting diode chip 3 secured on cooling plate 4. As shown in FIG. 3, cooling plate 4 of light-emitting diode device 1a is formed with a circular recess 4c in which a light reflective reflector 5 is secured in electrically isolated relation to cooling plate 4. Reflector 5 is formed with a conical or flaring inner surface 5a which gradually expands toward transmitter 2. Light emitting diode chip 3 is secured on circular recess 4c of cooling plate 4 in an inner hole 5d defined by inner surface 5a of reflector 5 so that one electrode (bottom electrode) of diode chip 3 is electrically connected to cooling plate 4.

As shown in FIG. 3, diode device 1a comprises a first outer lead 9a electrically connected to cooling plate 4, a second outer lead 9b electrically connected to the other electrode (upper electrode) of diode chip 3, a lead wire 10 electrically connecting upper electrode of diode chip 3 and second outer lead 9b, a plastic encapsulant 7 enveloping side surfaces 4b and main surface 4a of cooling plate 4, a side surface 5b of reflector 5 and each inner end of outer leads 9, and a lens portion 11 covering inner hole 5d and upper surface 5c of reflector 5 (FIG. 1).

Cooling plate 4 is formed of metallic material such as copper, aluminum, copper alloy or aluminum alloy having the thermal conductivity more than 190 kcal/mh° C., and reflector 5 is formed of electrically conductive metallic material same as that of cooling plate 4. When diode chip 3 radiates light by passing through diode chip 3 heavy current on the order of 100 mA, diode chip 3 can continue lighting for a long period of time with the high intensity, exhausting outside through cooling plate 4 heat generated during the lighting operation of diode chip 3.

Positioned and fit in circular recess 4c on cooling plate 4 is reflector 5 adhered on cooling plate 4 by electrically isolated bonding agent 12 such as thermosetting epoxy resin, but a part of main surface 4a on cooling plate 4 is exposed through inner hole 5d of reflector 5. Minimum inner diameter of inner hole 5d is larger than width or side length of diode chip 3 which can be adhered on exposed main surface 4a of cooling plate 4 through electrically conductive bonding agent 13 surrounded by and within inner surface 5a of reflector 5. By virtue of reflector 5, diode chip 3 can emit light with the high output and uniform brightness luminance or intensity. As shown in FIG. 3, reflector 5 in this embodiment comprises a generally cylindrical main body 5f formed with central conical inner hole 5d, and a notch 5e directly passing through main body 5f from inner hole 5d to side surface 5b between diode chip 3 and second outer lead 9b. Lead wire 10 passes through notch 5e to connect diode chip 3 and second outer lead 9b. Plastic encapsulant 7 is formed of thermosetting resin such as epoxy resin. Lens portion 11 is formed of light transmissible resin into a generally hemispherical shape, but lens portion 11 may be omitted if reflector 5 can reflect light from diode chip 3 outside with the full directivity.

In manufacturing light-emitting diode device 1a shown in FIG. 3, a leadframe assembly 19 shown in FIG. 4 is prepared by press-forming a metallic strip made of copper, aluminum or alloy thereof. Leadframe assembly 19 comprises a plurality of openings 19a formed at given intervals, and a plurality of outer leads 9 extending in openings 19a. Cooling plates 4 are formed in openings 19 with circular recess 4c in which reflector 5 is to be adhered via electrically insulative adhesive 12 as shown in FIG. 3. Otherwise, cooling plate 4 may be provided by integrally or coincidentally forming with reflector 5.

Then, through electrically conductive adhesive 13 such as solder or electrically conductive paste and by means of well-known die bonder, diode chip 3 is secured on main surface 4a of cooling plate 4 exposed in inner hole 5d within circular recess 4c. Subsequently, lead wire 10 is connected to electrode 8 of diode chip 3 at one end and outer lead 9 at the other end, and plastic encapsulant 7 is formed to seal main surface 4a and side surfaces 4b of cooling plate 4, side surface 5b of reflector 5 and each inner end of outer leads 9. Next, diode device 1a is attached to transmitter 2 by fitting each end 2a of transmitter 2 into outer surface of reflector 5 toward diode chip 3.

Description on well-known structure and manufacture of diode chip 3 is omitted herein. Not shown but, diode chip 3 comprises a semiconductor substrate, anode and cathode electrodes formed on one and the other main surfaces of the substrate, the cathode electrode being electrically connected to cooling plate 4. Also, the other electrode of diode chip 3 is electrically connected to second outer lead 9b by means of lead wire 10 utilizing a well-known wire bonding technique. After that, leadframe assembly 19 is attached to a forming mold not shown to form plastic encapsulant 7 utilizing a well-known transfer molding technique to seal main surface 4a and side surfaces 4b of cooling plate 4, side surface 5b of reflector 5 and each inner end of outer leads 9. Simultaneously, upper surface of plastic encapsulant 7 is formed with an annular groove 7a in which end 2a of transmitter 2 is fit. However, this is not limited to a transfer molding technique, a well-known potting technique may be used to form plastic encapsulant 7. Specifically, potting technique can be applied to form plastic encapsulant 7 around diode device 1a and transmitter 2 arranged in position to bond diode device 1a and both ends of transmitter 2 by plastic encapsulant 7.

As shown in FIG. 1, in semiconductor light-emitting device 1 having transmitter 2, attached to upper surface 5c of reflector 5 is lens portion 11 made of light-transmittable resin, and unwanted portions are deleted from leadframe assembly 19 to finish semiconductor light-emitting device 1a. In this embodiment, as lead wire 10 is positioned through notch 5e of reflector 5, diode chip 3 and second outer lead 9b can easily be connected by straight and shortened lead wire 10 preventing deformation of lead wire 10. In this case, as lead wire 10 does not need to pass above upper surface 5c of reflector 5 in the curved configuration, disconnection hardly happens to lead wire 10 to enhance reliability in quality of diode device 1a. Moreover, in accordance with this embodiment, structure of reflector 5 can be made in smaller size with reduced diameter of reflector 5, and at the same time, it can be made with increased height for improvement of the light directivity and axial brightness. Also, the shielding structure of diode chip 3 by cooling plate 4 and reflector 5 prevents invasion of foreign matter such as moisture into diode chip 3 to restrict deterioration of diode chip 3 by foreign matter to accomplish the highly reliable structure. Alternatively, without using lead wire 10, a semiconductor chip of bump electrodes directly electrically connected to outer leads 9 can be used.

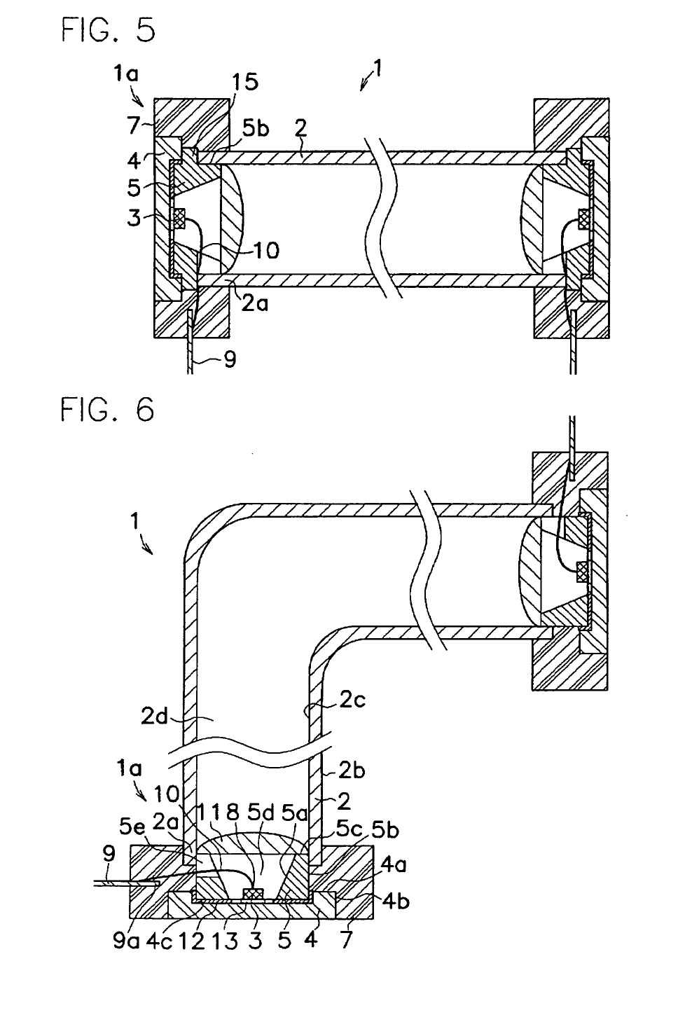

As shown in FIGS. 1 and 2, transmitter 2 is coupled to a pair of light emitting diode device 1a by fitting both ends 2a of transmitter 2 into annular groove 7a of plastic encapsulant 7 which seals cooling plate 4 and reflector 5. In this arrangement, diode chip 3 irradiates light directly into transmitter 2 through both ends 2a with the minimum amount of light leakage for high light transfer efficiency. As shown in FIG. 5, reflector 5 can be formed with an annular step 15 on side surface 5b of reflector 5 to bring ends 2a of transmitter 2 into contact to step 15 to firmly arrange ends 2a of transmitter 2 in position on diode device 1a.

In the present embodiment of semiconductor light-emitting device 1, when electric current is supplied through outer leads 9, diode chip 3 irradiates light which is introduced through reflector 5 and lens portion 11 into transmitter 2 from end 2a with the high directivity and full axial brightness. Conical inner surface 5a of reflector 5 is designed to effectively reflect light from diode chip 3 toward lens portion 11. In the semiconductor light-emitting device 1 shown in FIG. 1, inclined angle of conical inner surface 5a is equal to or more than 30 degrees with respect to bottom surface of conical inner surface 5a to make light from diode chip 3 converge through lens portion 11 with the high directivity.

In the present invention, light from diode chip 3 enters transmitter 2 from both ends 2a, and then radiates from peripheral surface 2b out of transmitter 2. Outgoing position of light on peripheral surface 2b depends on incident angle of light from diode chip 3 into transmitter 2, specifically, a part of light coming from diode chip 3 goes out of peripheral surface 2b of transmitter 2 in an area relatively near diode chip 3, but another part of light coming from diode chip 3 is reflected on transmitter 2 or some reflector in transmitter 2, and then radiates from peripheral surface 2b of transmitter 2 in another area relatively away from diode chip 3. In the semiconductor light-emitting device 1, selecting a suitable length of transmitter 2 enables light from diode chip 3 to radiate with the substantially uniform brightness throughout a whole length of peripheral surface 2b. Light scattering material may be mixed in transmitter 2. In particular, solid transmitter 2 without cavity 2d can include light scattering material blended therein to irradiate light from diode chip 3 to the outside throughout a whole length of peripheral surface 2b. Otherwise, light scattering material is mixed with transparent material such as resin which then can be filled in cavity 2d of transmitter 2. In another aspect, transmitter 2 is not limited to a straight rod shape shown in FIGS. 1 and 2, and can be formed into a bent shape such as substantially L-shape shown in FIG. 6 or into a curved shape not shown.

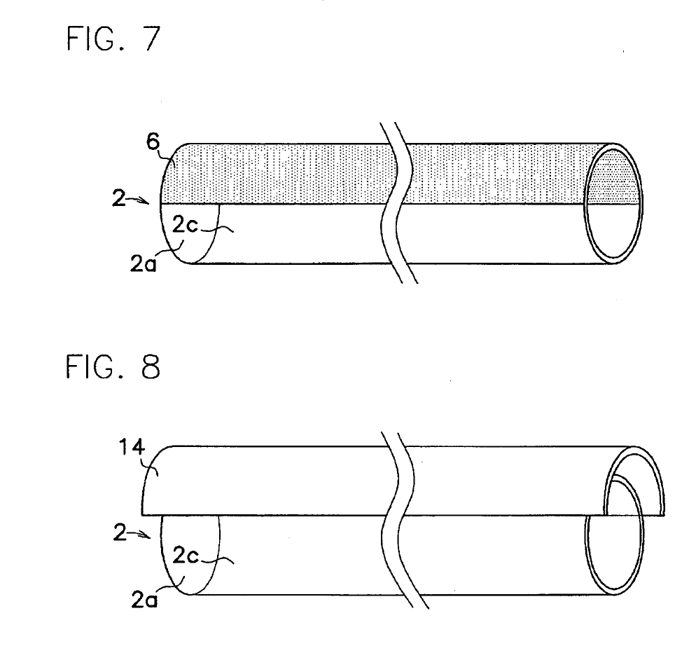

As shown in FIG. 7, the present invention also contemplates provision of a light-reflective film 6 which covers at least a part of outer or inner circumferential surface 2b or 2c of transmitter 2 to irradiate light reflected on light-reflective film 6 from an uncovered area of transmitter 2 with the higher brightness. For example, light-reflective film 6 can be formed of a thin metallic coating such as gold or aluminum applied by vapor deposition on a longitudinal and semicircular outer circumferential surface 2b of hollow cylindrical transmitter 2. Light in transmitter 2 is reflected on film 6 coated on semicircular outer surface 2b, and then intensively emitted through the remaining uncoated semicircular outer surface 2b out of transmitter 2 to increase the output amount of light in a selected direction. Alternatively, as shown in FIG. 8, a separate reflex plate 14 can be provided to surround a half of transmitter 2 in a spaced relation thereto. Reflex plate 14 is formed of metal such as aluminum to produce the same effect as that of light-reflective film 6.

The semiconductor light-emitting device according to the present invention can provide, for example, a backlight source for LCD. Not shown but, a single or plurality of semiconductor light-emitting devices are lengthwise arranged toward and along a side end surface or side end surfaces of a light guide plate to introduce linear light from the light-emitting devices 1 into light guide plate through side end surfaces. Linear light from the light-emitting devices 1 is reflected in light guide plate and irradiated from a surface of light guide plate to the outside to illuminate LCD panel from the back. The invention's semiconductor light-emitting device can fully illuminate LCD panel from the back through light guide plate into which linear light not point light is introduced with the reduced longitudinally non-uniform brightness. For example, when a plurality of the semiconductor light-emitting devices according to the present invention are applied to a backlight source, they are longitudinally apposed to produce blue, green and red lights. Otherwise, a plurality of the semiconductor light-emitting devices to produce different color lights can be apposed in the thickness direction of the light guide plate. In addition, a plurality of light-emitting diodes for producing different color lights may be incorporated in a single semiconductor light-emitting device. Configuration of transmitter 2 is not limited to hollow or solid cylindrical shape, and may be formed into a hollow or solid stem or rod shape of polygonal section to adapt it for shape of side end surface of light guide plate. In the present invention, a point light from a light-emitting diode is converted into a linear light which is then transformed into an improved plane emission from light guide plate for backlight source with the uniform brightness and well-balanced light colorific tone.

Further, the semiconductor light-emitting device according to the present invention may be used in combination with a prior art CCFL tube. As mentioned above, while CCFL tube produces light inclusive of poor red and green color light components, combination of the semiconductor light-emitting device and CCFL tube can produce light of good balance in colorific tone because light-emitting diode 3 emits light inclusive of rich red and green color light components, and it can compensate drawback by CCFL tube. Also, in applying the semiconductor light-emitting device according to the present invention to backlight source, it may be of the subjacent type wherein the light-emitting device is mounted under liquid crystal panel, as well as the side edge type wherein light-emitting device is mounted along and toward side edge of LCD.

The foregoing embodiments according to the present invention gain the following functions and effects:

[1] Light from light-emitting diode as a point light source can be converted through transmitter 2 into a linear light of the substantially uniform brightness and well-balanced colorific tone;

[2] Heat produced from light-emitting diode chip 3 can be radiated to the outside through cooling plate 4 and reflector 5 to accomplish continuous lighting of light-emitting diode 3 for a long time with the high brightness;

[3] Light from light-emitting diode chip 3 can directly be introduced into transmitter 2 from both ends 2a thereof with the minimum amount of light leakage for good light conversion efficiency from point light to linear light;

[4] Light can be irradiated with the substantially uniform brightness throughout a whole length of peripheral surface 2b from elongated light transmitter 2 whose length can be selected as required;

[5] Combination of semiconductor light-emitting device 1 and CCFL tube can produce light of good balance in colorific tone, compensating poor color light components from CCFL tube by semiconductor light-emitting device 1;

[6] Light reflective film 6 can be formed on outer or inner peripheral surface 2b or 2c of transmitter 2 to reflect light in transmitter 2 on light reflective film 6 and intensively emit it through film-free outer surface 2b with the high brightness;

[7] Reflector 5 can convert light from diode chip 3 into a high light output with the uniform brightness.

In applying the semiconductor light-emitting device according to the present invention to a backlight source of LCD, actual examples thereof are described hereinafter.

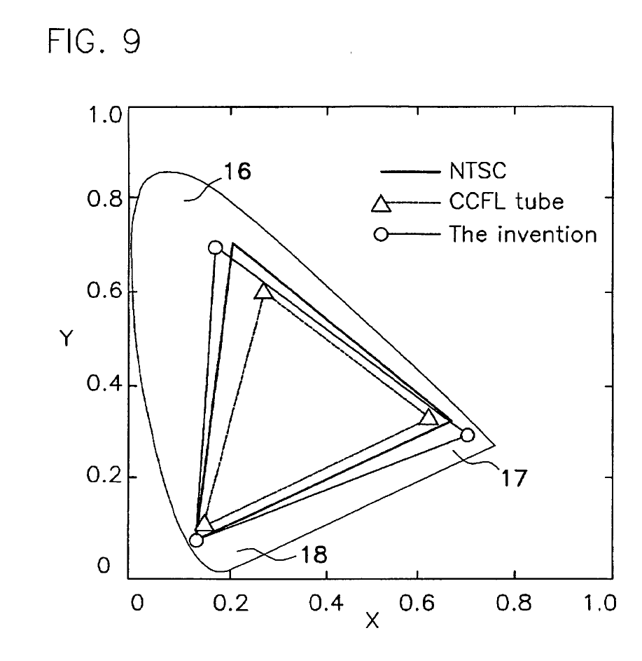

Hollow cylindrical light transmitters 2 were made of glass, and each cavity 2d of transmitter 2 was filled with air to prepare semiconductor light-emitting devices 1. A value of electric current through light-emitting diodes 3 was set to 100 mA. Then, backlight sources for LCD were prepared by combining semiconductor light-emitting devices 1 for emitting blue, green and red color lights. As a result, plane illumination was carried out with the well-balanced light colorific tone by linear light of the substantially uniform brightness. FIG. 9 is a gamut map of a chromaticity reproductibility according to the CIE (Commission Internationale de I'Ecairage) Standard Colorimetric System showing graphs for comparison in chromaticity reproductibility area of the semiconductor light-emitting device according to the present invention and CCFL tube. In FIG. 9, 16, 17 and 18 in a horseshoe-shaped area respectively denote green, red and blue regions in chromaticity reproductibility area wherein circle mark, triangle mark and no mark respectively indicate chromaticity reproductibility areas by the semiconductor light-emitting device according to the invention, CCFL tube and regulation of NTSC. As understood from FIG. 9, CCFL tube represented poor green and red light components compared to the chromaticity reproductibility area regulated by NTSC, the semiconductor light-emitting device of the invention exhibited rich green and red light components in addition to full blue light component. In other words, the semiconductor light-emitting device can provide a red color rendering which prior art CCFL tube is lacking in, satisfying requirements by NTSC. When CCFL tube for producing white light is combined with a semiconductor light-emitting device 1 for producing red light, similar effects can be obtained during the lighting operation. Further, when CCFL tubes for producing blue and green lights are combined with a semiconductor light-emitting device 1 for producing red light, similar effects can be obtained during the lighting operation. In the present invention, a plurality of semiconductor light-emitting device 1 could adapt in combination for size of a display, namely for a large screen to provide a backlight source for LCD with the high output and uniform brightness. Accordingly, it has been found that the semiconductor light-emitting device alone or in combination with CCFL tube can be used as a backlight source for LCD.

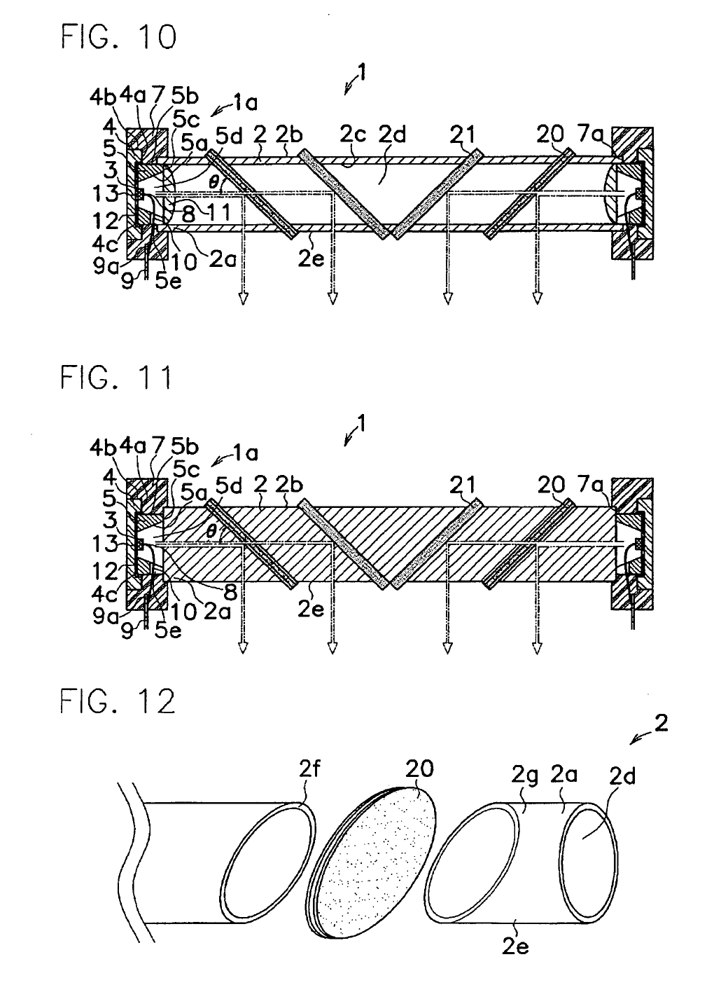

Now referring to FIGS. 10 to 18, embodiments of linear light sources according to the present invention are described hereinafter.

As shown in FIGS. 10 and 11, a linear light source 1 of an embodiment according to the present invention comprises an elongated or stick-like light transmitter 2 having an irradiation surface 2e, light-emitting diode chips 3 as semiconductor light-emitting elements for irradiating light into transmitter 2 through two ends 2a of transmitter 2, and a pair of half-mirrors 20 arranged in transmitter 2 for reflecting a part of light from diode chip 3 to the outside through irradiation surface 2e.

Light transmitter 2 is formed of transparent or translucent glass or light-transmissible resin such as epoxy, acrylic, polyimide or polycarbonate resin. FIG. 10 illustrates linear light source 1 provided with hollow cylindrical light transmitter 2 formed with a cavity 2d in which for example air or nitrogen gas is filled, but transparent or translucent gel or solid resin may be disposed or filled in cavity 2d. FIG. 11 depicts linear light source 1 of solid cylindrical light transmitter 2 without cavity.

Half-mirror 20 is also referred to as semi-transparent or translucent mirror or dielectric multi-layered film mirror, and formed by well-known method such as vacuum vapor deposition technique to permeate, reflect or absorb light in a specific wavelength range, utilizing optical interference or absorption resulted from variation in index of refraction, thickness or number of layered films. Half-mirror 20 of this embodiment comprises dielectric multi-layered films of alternate dielectrics having the high and low refractive index with their optical film of quarter wavelength to transmit a part of incident light but reflect the other part of incident light. For example, it may have a reflective mirror structure of alternately accumulated light-permeable thin films of titanium dioxide (TiO₂) (high refractive index) and silicon dioxide (SiO₂) (low refractive index) mounted on a glass substrate to reflect light in a specific wavelength range including a central wavelength. Half-mirror 20 may include metallic thin films instead of dielectric thin films, but preferably includes dielectric thin films with less optical absorption.

As shown in FIGS. 10 and 11, light transmitter 2 includes a plurality of half-mirrors 20 attached across and in the inclined condition at a certain angle to a longitudinal central line of light transmitter 2. Half-mirrors 20 function to divert or deflect visible light from light-emitting diode chip 3 toward irradiation surface 2e to emit light with the uniform brightness throughout a whole length of irradiation surface 2e from elongated light transmitter 2. In these embodiments, each half-mirror 20 formed into a disk-shape is sandwiched between a plurality of segments of light transmitter 2. In detail, as shown in FIG. 12, elongated transmitter 2 is beveled at an inclined angle to outer surface 2b to insert and firmly set disk-like half-mirror 20 between cut surfaces 2f of transmitter 2. Not shown but a slant slit is formed in transmitter to attach disk-like half-mirror 20 in the slit without beveling transmitter 2.

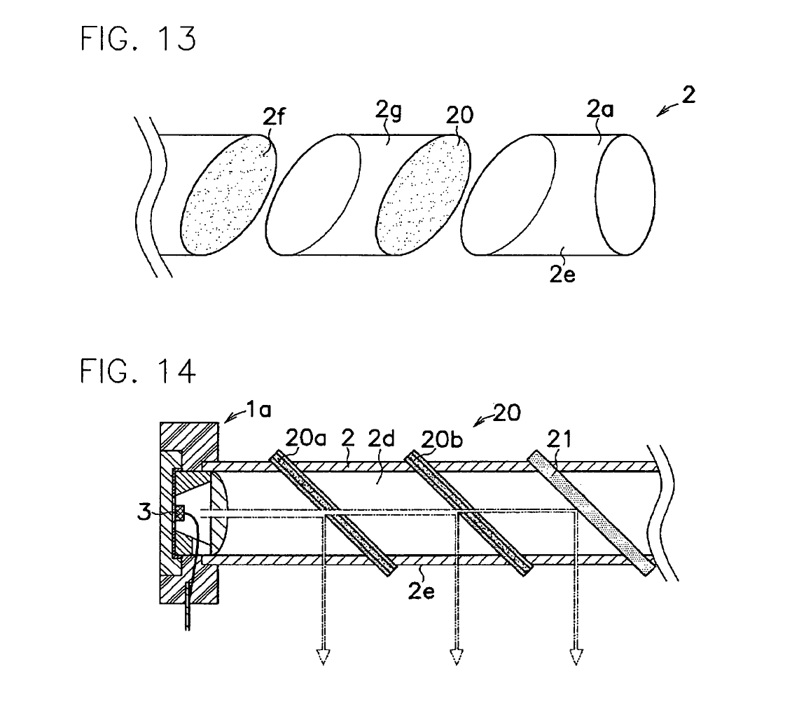

In another structure of transmitter 2 having half-mirrors 20, a layer of half-mirror 20 is formed by vapor deposition on at least one beveled surface of plural segments 2g of transmitter 2, and then opposite beveled surfaces of segments 2 are brought into contact to each other. Specifically, as illustrated in FIG. 13, solid cylindrical transmitter 2 is obliquely cut to form into a half-mirror 20 a dielectric thin film or metallic thin film on one of cut oblique surfaces 2f by vapor deposition, and then cut oblique surfaces 2f are contacted and fastened to each other to assemble transmitter 2. An angle for setting half-mirrors 20 in transmitter 2 is determined as required to irradiate light from diode chip 3 through irradiation surface 2e of transmitter 2 with the equal brightness distribution, keeping dimension of transmitter 2, number and arrangement of half-mirrors 20 in mind.

In another aspect, transmitter 2 may incorporate total reflection mirrors 21 located therein inside of half-mirror 20 to reflect light passing through half-mirror 20 toward the outside of transmitter 2. Total reflection mirror 21 can be prepared for example by plating silver on a glass plate and mounted in transmitter 2 in a similar manner as that mentioned above. A pair of total reflection mirrors 21 are positioned on the central side of a pair of half-mirrors 20 to increase reflected amount of visible light from diode chip 3 toward irradiation surface 2e. In these embodiments, half and total reflection mirrors 20 and 21 are mounted in transmitter 2 in the inclined fashion relative to diode chip 3 and peripheral surface 2b. In linear light source 1 shown in FIGS. 10 and 11, half and total reflection mirrors 20 and 21 are fixed at an angle of 45 degrees relative to a central axis of transmitter 2 to deflect visible light from diode chip 3 substantially perpendicularly toward irradiation surface 2e of transmitter 2. As shown in FIGS. 10 and 11, half and total reflection mirrors 20 and 21 are attached to transmitter 2 at the same inclination angle, but may be attached at different inclination angles. Thus, light from diode chips 3 introduced from two ends 2a of transmitter 2 is reflected on half-mirrors or on total reflection mirrors 21 after passing through half-mirrors 20 to the outside of transmitter 2 through irradiation surface 2e.

Linear light sources 1 shown in FIGS. 10 and 11 comprise each pair of half and total reflection mirrors 20 and 21 in transmitter 2, however, two pairs or more of half-mirrors 20 per a pair of total reflection mirrors 21 may be provided. In this case, half-mirrors 20 may have the lower light reflectance and higher light transmittance the closer they are to diode chip 3. As brightness of light from diode chip 3 becomes lower further away from diode chip 3, if half-mirrors 20 have the lower light reflectance and higher light transmittance the closer they are to diode chip 3, the linear light source can reduce difference in reflected light amount between half-mirrors 20a and 20b closer to and further from diode chip 3 to irradiate light from diode chip 3 out of transmitter 2 with the more uniform brightness.

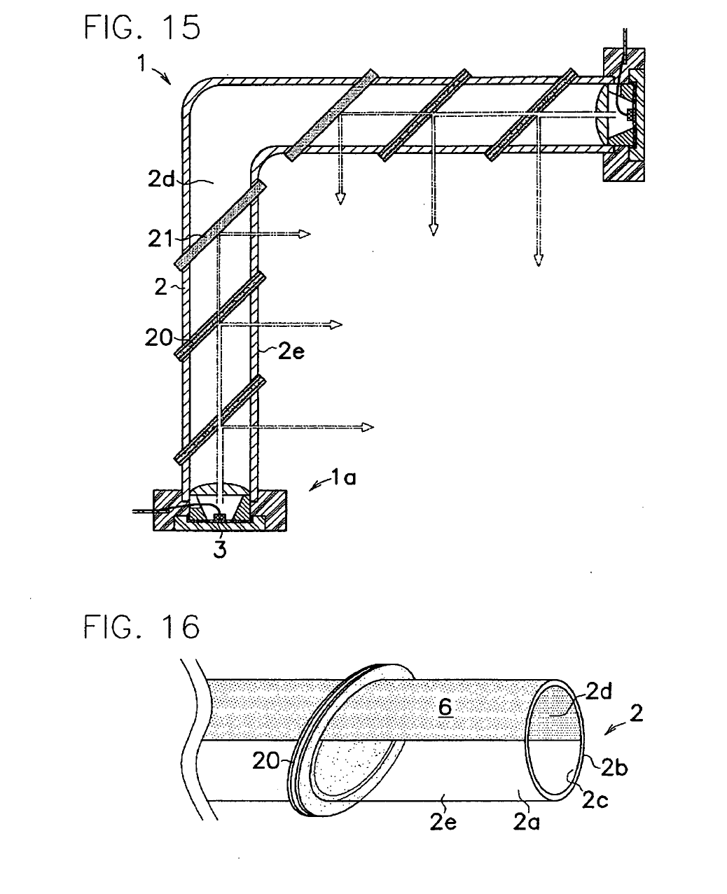

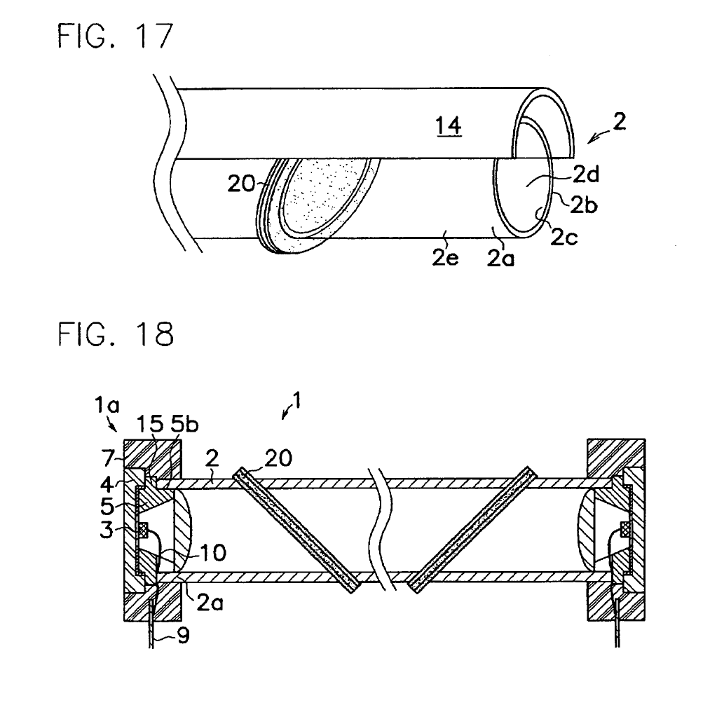

Not only in a straight configuration shown in FIGS. 10 and 11, but also transmitter 2 can be formed into a generally elbow or bent shape as shown in FIG. 15 or curved shape. Linear light source 1 shown in FIG. 1 may have half-mirrors 20 whose light reflectance and transmittance are adjusted as necessary or a plurality of half-mirrors 20 and total reflection mirrors 21 whose spaced distance therebetween and setting angle can be adjusted as necessary to balance or vary visible light amount irradiated through irradiation surface 2e of bent transmitter 2. In this embodiment, as shown in FIG. 16, a light reflective film 6 may be formed on at least a part of outer or inner circumferential surface 2b or 2c of transmitter 2 to irradiate higher intensity light reflected on reflective film 6 through film-free irradiation surface 2e. Transmitter 2 of FIG. 16 is formed into a hollow cylindrical shape having peripheral surface 2b whose half side bears lengthwise a metallic reflective film 6 such as gold or aluminum formed by vapor deposition. Light in transmitter 2 is reflected on reflective film 6 to converge light on the side of irradiation surface 2e to enhance the light output through irradiation surface 2e. Also, as shown in FIG. 17, a separate reflex plate 14 may be provided in spaced relation to transmitter 2 for envelopment. Reflex plate 14 is formed of metal such as aluminum or nonmetal such as white resin to produce similar effects as those by light reflective film 6.

In this embodiment, attached to both ends 2a of transmitter 2 are light-emitting diode devices 1a which can be prepared by the same method as those mentioned above for semiconductor light-emitting device 1 shown in FIG. 3 and light-emitting diode device 1a shown in FIG. 4. As shown in FIGS. 10 and 11, transmitter 2 is secured to light-emitting diode devices 1a by putting each end 2a of transmitter 2 into circular groove 7a formed in plastic encapsulant 7 encircling cooling plate 4 and reflector 5 to thereby cause light from light-emitting diode chips 3 to directly enter transmitter 2 from both ends 2a with the minimum amount of light leakage for good light conversion efficiency. Further, as shown in FIG. 18, reflector 5 can be formed with an annular step 15 on side surface 5b of reflector 5 to bring ends 2a of transmitter 2 into contact to step 15 to firmly arrange ends 2a of transmitter 2 in position on diode device 1a.

The structure according to the present invention enables visible light from light-emitting diode 3 to directly and efficiently go into light transmitter 2 from both ends 2a with the least amount of light leakage. In this case, light-emitting diode chip 3 provides a point light source from which visible light directly or after reflected on inner surface 5a of reflector 5 passes lengthwise in transmitter 2, and therefore, very little amount of visible light is irradiated from light-emitting diode chip 3 directly toward irradiation surface 2e of transmitter 2. The present invention, nevertheless, can accomplish substantially uniform brightness of illumination through whole irradiation surface 2e of transmitter 2 by reflecting light from visible light-emitting diode chip 3 on half-mirrors 20.

The linear light source according to the present invention can be used for example as a backlight source for LCD in a similar method as that for the above-mentioned semiconductor light-emitting device 1. Further, light from light-emitting diode chip 3 can be irradiated out of transmitter 2 after light is transformed into a different wavelength by fluorescent material film formed on inner peripheral surface 2c of transmitter 2 or fluorescent material mixed in filler within transmitter 2. In this case, diode chips for emitting blue or ultra-violet light may be used as light-emitting diode chip 3 to produce white color light.

The embodiments of the present invention offer the following functions and effects:

[1] Half-mirror 20 reflects visible light from light-emitting diode 3 to increase the amount of visible light toward irradiation surface 2e of transmitter 2;

[2] Reflection of light from diode chip 3 as a point light source by half-mirror 20 provides linear light with the substantially uniform brightness and well-balanced colorific tone;

[3] Light emitting diode chip 3 directly and efficiently irradiates light into transmitter 2 from both ends 2a thereof with the minimum light leakage;

[4] Half-mirrors 20 have the lower light reflectance and higher light transmittance, the closer they are to diode chip 3 to reduce difference in reflected light amount between half-mirrors to irradiate light from diode chip 3 out of transmitter 2 with the uniform brightness;

[5] A pair of total reflection mirrors 21 positioned on the central side of a pair of half-mirrors 20 can increase reflected amount of visible light from diode chip 3 toward irradiation surface 2e on the central side; and

[6] Light from linear light source 1 can compensate poor light color components from CCFL tube combined with linear light source 1.

The following describes an embodiment of a linear light source according to the present invention applied to a backlight source for LCD.

Linear light sources 1 were prepared each which comprises a hollow cylindrical transmitter 2 formed of glass, a pair of half-mirrors 20 mounted in transmitter at an inclined angle of 45 degrees relative to central axis of diode chip 3 and irradiation surface 2e of transmitter 2, and a pair of total reflection mirrors 21 located on the central side of half-mirrors 20 in transmitter 2 at the same angle as that for half-mirrors 20. A value of electric current through diode chip 3 was set to 100 mA. Linear light sources for emitting blue, green and red color light were assembled into backlight sources for LCD which indicated a fact that half and total reflection mirrors 20 and 21 reflected light from point light source by diode chip 3 through both ends 2a into transmitter 2 toward and out of irradiation surface 2e with the substantially homogeneous and high brightness without irregularity in intensity of light. Also, linear light source 1 provides a linear light emission for light guide plate which produces plane light emission from an illumination surface with the well-balanced colorific tone. Further, obtained linear light source 1 generated light rich in red and green light components satisfactory for requirements by NTSC as shown by FIG. 9 on gamut map of a chromaticity reproductibility. Combined linear light sources and CCFL tube also revealed similar consequences as those mentioned above. Thus, it has been found that the linear light source 1 according to the present invention itself alone or in combination with CCFL tube well functions as a backlight source for LCD.

As above-mentioned, the semiconductor light-emitting device and linear light source according to the present invention can provide linear light emission rich in red and green light components for well-balanced colorific tone with the substantially homogeneous light intensity.

### INDUSTRIAL APPLICABILITY

The semiconductor light-emitting device and linear light source according to the present invention are satisfactorily applicable to a backlight source for LCD.

1. A semiconductor light-emitting device comprising an elongated light transmitter (2); a pair of metallic heat sinks (4) disposed on opposite ends (2a) of the transmitter (2); and a semiconductor light-emitting element (3) mounted each of said heat sinks (4) toward the transmitter (2) for emitting light which is introduced into the transmitter (2) from the both ends thereof to radiate light outside from an outer peripheral surface (2b) of the transmitter (2).

2. The semiconductor light-emitting device of claim 1, wherein each of said heat sinks (4) comprises a reflector (5) integrally formed with or secured on a main surface (4a) of the heat sink (4),
said reflector (5) has a flaring inner surface (5a) which gradually expands toward said transmitter (2); and
said semiconductor light-emitting element (3) is surrounded by the inner surface (5a) of said reflector (5).

3. The semiconductor light-emitting device of claim 1, further comprises a light reflective film (6) formed on at least a portion of outer or inner peripheral surface (2b) of the transmitter (2).

4. The semiconductor light-emitting device of claim 1, wherein said transmitter (2) is formed of transparent or translucent glass or resin into a hollow or solid cylindrical shape; and
each end of said transmitter (2) is received in an annular groove (7a) formed on a plastic encapsulant (7) which envelops said heat sink (4).

5. A method for producing a semiconductor light-emitting device, comprising the steps of:
providing heat sinks (4) each having a reflector (5);
securing a semiconductor light-emitting element (3) on a main surface (4a) of each heat sink (4) within said reflector (5);
electrically connecting an electrode on said semiconductor light-emitting element (3) and an outer lead (9) through a lead wire (10);
forming a plastic encapsulant (7) which envelops the main and side surfaces (4a) of the heat sink (4), a side surface of the reflector (5) and an inner end of the outer lead (9); and
joining each end of an elongated light transmitter (2) to the reflector (5) toward the semiconductor light-emitting element (3).

6. A linear light source comprising an elongated light transmitter (2) which has an irradiation surface (2e) and two ends; a semiconductor light-emitting element (3) for emitting light introduced into said light transmitter (2) from each of two ends thereof; and a plurality of half-mirrors (20) provided in said light transmitter (2) for reflecting light introduced into said light transmitter (2) from light-emitting element (3) out of said light transmitter (2) through the irradiation surface (2e).

7. The linear light source of claim 6, wherein a plurality of said half-mirrors (20) are provided in said light transmitter (2), said half-mirrors (20) being across and inclined at a certain angle to a longitudinal central line of said light transmitter (2).

8. The linear light source of claim 7, wherein said half-mirrors (20) have the lower light-reflectivity and the higher light permeability, the closer said half-mirrors (20) are diposed to the semiconductor light-emitting element (3).

9. The linear light source of claim 6, wherein at least one total reflection mirror (21) is provided inside said half-mirrors (20) in the light transmitter (2) for reflecting light permeated through said half-mirrors (20) to the outside of said light transmitter (2) through said irradiation surface (2e).

10. The linear light source of claim 6, wherein said half-mirror formed into a plate shape is sandwiched between a plurality of segments (2g) of said light transmitter (2).

11. The linear light source of claim 6, wherein said half-mirrors (20) are formed by vapor deposition on at least one inclined surface of plural segments (2g) of said light transmitter (2), and said inclined surfaces of plural segments (2g) are in contact to each other.
